(19) United States
(12) Patent Application Publication
(10) Pub. No.: US 2009/0251979 A1
(43) Pub. Date: Oct. 8, 2009

(54) METHOD FOR SUPPRESSING CURRENT LEAKAGE IN MEMORY

(75) Inventor: Chuan-Jen Chang, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: NANYA TECHNOLOGY CORPORATION, Taoyuan (TW)

(21) Appl. No.: 12/136,052

(22) Filed: Jun. 10, 2008

(30) Foreign Application Priority Data
Apr. 8, 2008 (TW) 97112703

(51) Int. Cl. G11C 7/00; G11C 5/14

(52) U.S. Cl. 365/203; 365/227

(57) ABSTRACT

A method for suppressing a current leakage of a memory is provided. The memory at least includes a memory cell, an equalizing circuit, a current limiter, a word line and a pair of complementary bit lines. The method includes: having the memory cell entering a pre-charging mode; having the equalizing circuit and the current limiter being normally operated, so as for pre-charging the pair of complementary bit lines; applying a periodic control signal to the current limiter for controlling the current limiter to be either conducting or non-conducting, in which when the current limiter is non-conducting, a standby current leakage of the memory is suppressed, in which the standby current leakage is caused by a short circuit between the word line and the pair of complementary bit lines.

### CROSS-REFERENCE TO RELATED APPLICATION

This application claims the priority benefit of Taiwan application serial no. 97112703, filed on Apr. 8, 2008. The entirety of the above-mentioned patent application is hereby incorporated by reference herein and made a part of specification.

### BACKGROUND OF THE INVENTION

1. Field of the Invention

The present invention generally relates to a method for compressing a current leakage of a memory, and more particularly, to a method for suppressing a current leakage of a memory in a standby mode by adaptively turning on/off a current limiter.

2. Description of Related Art

Dynamic random access memories (DRAM) are very popular semiconductor memory components. A typical memory cell inside a DRAM is usually configured by a capacitor. Such a memory cell is conventionally coupled to a bit line via a transistor. The transistor has a gate electrically connected to the bit line, and a source and a drain respectively electrically connected to the bit line and the capacitor.

Generally, when operating in a standby mode, the memory cell is usually executed with a pre-charging process to pre-charge the bit line and a complementary bit line to predetermined voltage levels. For example, the bit line and the complementary bit line are pre-charged to a power supply voltage VDD, a half of the power supply voltage VDD/2, a ground voltage VSS, or other reference voltages.

When performing a reading operation, a word line is at a logic high level, and therefore the transistor is conducting, so that charges stored in the capacitor can be transmitted via the transistor to the bit line. As such, a voltage of the bit line will be caused with a mild variation, while the complementary bit line is maintained at the predetermined voltage level. In such a way, there is a mild voltage difference occurred between voltage levels of the bit line and the complementary bit line, and the mild voltage difference may be amplified by a sense amplifier.

In a practical layout, a bit line is often disposed very close to a word line, and therefore a short circuit is likely caused between the bit line and the word line, which also causes a current leakage. When the memory is performing a reading/writing operation, the power consumption caused by the current leakage is only a little and can be neglected. However, when the memory is working in a standby mode, it is very desirable to reduce the power consumption caused by the current leakage.

Correspondingly, the present invention provides a method for compressing a current leakage of a memory when operating in a standby mode, and for eliminating unnecessary power consumption.

### SUMMARY OF THE INVENTION

Accordingly, the present invention is directed to a method for compressing a current leakage of a memory. The present invention employs a periodic signal for controlling a conducting time for pre-charging. When the periodic signal is logic low, a circuit for pre-charging is non-conducting, during which there is no leakage current.

The present invention provides a method for suppressing a current leakage of a memory. The memory at least includes a memory cell, an equalizing circuit, a current limiter, a word line and a pair of complementary bit lines. The method includes: having the memory cell entering a pre-charging mode; having the equalizing circuit and the current limiter being normally operated, so as for pre-charging the pair of complementary bit lines; applying a periodic control signal to the current limiter for controlling the current limiter to be either conducting or non-conducting, in which when the current limiter is non-conducting, a standby current leakage of the memory is suppressed, in which the standby current leakage is caused by a short circuit between the word line and the pair of complementary bit lines.

According to another embodiment of the present invention, a method for suppressing a current leakage of a memory is provided. The memory at least includes a memory cell, an equalizing circuit, a current limiter, a word line, and a pair of complementary bit lines. The method includes: having the memory cell entering a pre-charging mode; having the equalizing circuit and the current limiter being normally operated, so as for pre-charging the pair of complementary bit lines; applying a periodic control signal to the current limiter for shortening a conducting time of the current limiter, and suppressing a standby current leakage of the memory, in which the standby current leakage is generated by a reference voltage over a short circuit between the word line and the pair of complementary bit lines, in which the logic low level of the periodic control signal is related to a negative pre-charging voltage of the word line.

Generally, the embodiments of the present invention employ a periodic control signal for intermittently pre-charging a pair of complementary bit lines when the memory is in a pre-charging mode, for effectively suppressing a current leakage, while maintaining the pair of complementary bit lines at a status of pre-charging.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram illustrating a memory.

FIG. 2 is a time sequence diagram of a control voltage Vint employed for suppressing a current leakage according to an embodiment of the present invention.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

According to an embodiment of the present invention, a periodic control voltage is employed for controlling a current limiter of a memory to turn on or turn off, and thus compressing a current leakage between a bit line and a word line when the memory is in a standby mode.

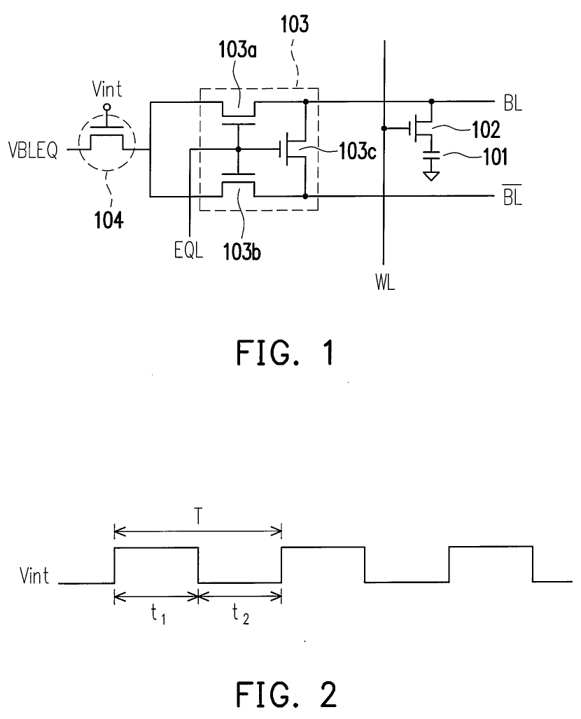

FIG. 1 is a schematic diagram illustrating a memory. Referring to FIG. 1, the memory includes a capacitor 101, a word line switch 102, an equalizing circuit 103, a current limiter 104, a word line WL, a bit line BL, and a complementary bit line B̅L̅. The equalizing circuit 103 includes equalizing circuit switches 103a, 103b, and 103c. The capacitor 101 can constitute a memory cell.

The word line switch 102 for example is a transistor having a gate electrically connected to the word line WL, a drain electrically connected to the bit line BL, and a source coupled to the capacitor 101.

When the word line WL is at a logic high level (representing that the memory cell is selected), the word line switch 102 is at a conducting status so that the bit line BL and the capacitor 101 are electrically conducting. Therefore, when the memory performs a writing operation, data of the bit line BL can be written into the capacitor 101, and when the memory performs a reading operation, data stored in the capacitor 101 an be read to the bit line BL.

When the word line WL is at a logic low level (representing that the memory cell is not selected), the word line switch 102 is at a non-conducting status so that the bit line BL and the capacitor electrically disconnected one from another.

The equalizing circuit switch 103a for example is a transistor, having a gate electrically controlled by an equalization signal EQL, a drain coupled to the current limiter 104, and a source coupled to the bit line BL.

The equalizing circuit switch 103b for example is a transistor, having a gate controlled by the equalization signal EQL, a drain coupled to the current limiter 104, and a source coupled to the complementary bit line B̅L̅.

The equalizing circuit switch 103c for example is a transistor, having a gate controlled by an equalization signal EQL, a drain coupled to the bit line BL, and a source coupled to the complementary bit line B̅L̅.

When the equalization signal EQL is at a logic high level, all of the equalizing circuit switches 103a, 103b, and 103c are at an on status. Meanwhile, a short circuit occurs between the bit line BL and the complementary bit line B̅L̅, and therefore charges of the bit line BL and the complementary bit line B̅L̅ can be mutually shared. At the same time, the bit line BL and the complementary bit line B̅L̅ are electrically connected to the current limiter 104, so that the bit line BL and the complementary bit line B̅L̅ are all pre-charged to a reference voltage VBLEQ (supposing that the current limiter 104 is at a conducting status).

When the equalization signal EQL is at a logic low level, the bit line BL and the complementary bit line B̅L̅ are disconnected one from another, and the bit line BL and the complementary bit line B̅L̅ are not electrically connected to the current limiter 104.

The current limiter 104 for example is a transistor having a gate serving as a control terminal controlled by a control voltage Vint. The current limiter 104 is coupled to the reference voltage VBLEQ and the equalizing circuit switches 103a and 103b.

When the control voltage Vint is at a logic high level, the current limiter 104 is at an on status, and the reference voltage VBLEQ is electrically connected to the equalizing circuit switches 103a and 103b.

When the control voltage Vint is at a logic low level, the current limiter 104 is at an off status, and the reference voltage VBLEQ cannot be electrically connected to the equalizing circuit switches 103a and 103b.

According to an embodiment of the present invention, the reference voltage is preferably at a half of a bit line high level VBLH. The bit line high level VBLH is a voltage level of the bit line at a logic high level.

FIG. 2 is a time sequence diagram of a control voltage Vint employed for suppressing a current leakage according to an embodiment of the present invention. Referring to FIGS. 1 and 2 together, the control voltage Vint is a periodic signal, such as a square wave having a duty cycle T. In a duty cycle T, the control voltage Vint is maintained at a logic high level for a time t1, i.e., conducting time of the current limiter 104, and is maintained at a logic low level for a time t2, i.e., non-conducting time of the current limiter 104, in which t1+t2=T.

When the memory is in the standby mode, if the equalization signal EQL is at a logic high level while the control voltage Vint is also at a logic high level, a short circuit occurs between the bit line BL and the complementary bit line B̅L̅, and the bit line BL and the complementary bit line B̅L̅ are electrically connected to the reference voltage VBLEQ. In other words, the bit line BL and the complementary bit line B̅L̅ are pre-charged to a level of the reference voltage VBLEQ. Meantime, if there is a short circuit occurs between the word line WL and the bit line BL (or between the word line and the complementary bit line B̅L̅), the part of the short circuit will allow the charges leaking from the bit line BL to the word line WL. As such a current leakage is generated.

On the contrary, when the control voltage Vint is at a logic low level, the reference voltage VBLEQ is disconnected from the bit line BL and the complementary bit line B̅L̅. Therefore, the bit line and the complementary bit line B̅L̅ are not pre-charged, and there won't be any current leakage flowing out from the word line WL.

In order to advantageously maintain the bit line and the complementary bit line B̅L̅ at the level of the reference voltage VBLEQ when the memory is in the standby mode so as to effectively suppress the current leakage, the duty cycle of the control voltage Vint and the frequency thereof should be adaptively controlled.

Further, when the word line WL is to be pre-charged to a negative voltage, the logic low level of the control voltage Vint can be determined to be an equivalent negative voltage.

Furthermore, it should be noted that the control voltage Vint can be any other synthesis sinusoidal wave, such as a triangular wave, which is adapted for maintaining the bit line BL and the complementary bit line B̅L̅ at the reference voltage VBLEQ when the memory is in the standby mode.

In summary, the present invention employs a periodic control voltage Vint for controlling the current limiter 104, so that the bit line BL and the complementary bit line B̅L̅ are not being continuously charged when the memory is in the standby mode. When the bit line BL and the complementary bit line B̅L̅ are not being charged, the current leakage won't occur, and therefore the current leakage of the memory when the memory is in the standby mode can be suppressed.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for suppressing a current leakage of a memory, the memory comprising at least a memory cell, an equalizing circuit, a current limiter, a word line and a pair of complementary bit lines, the method comprising:
having the memory cell entering a pre-charging mode;
having the equalizing circuit and the current limiter being normally operated, so as for pre-charging the pair of complementary bit lines; and
applying a periodic control signal to the current limiter for controlling the current limiter to be either conducting or non-conducting,
wherein when the current limiter is non-conducting, a standby current leakage of the memory is suppressed, and wherein the standby current leakage is caused by a short circuit between the word line and the pair of complementary bit lines.

2. The method according to claim 1, further comprising:
providing an equalization signal for controlling an operation of the equalizing circuit.

3. The method according to claim 1, wherein when the equalizing circuit is being normally operated, a short circuit occurs between the pair of complementary bit lines.

4. The method according to claim 1, further comprising:
applying a reference voltage to the current limiter.

5. The method according to claim 4, wherein when the equalizing circuit and the current limiter are being normally operated, the pair of complementary bit lines are pre-charged to the level of the reference voltage.

6. The method according to claim 5, wherein the reference voltage is a half of logic high level of the pair of complementary bit lines.

7. The method according to claim 1, wherein the periodic control signal is a square wave or a synthesis sinusoidal wave.

8. The method according to claim 1, wherein a logic low level of the periodic control signal is equivalent to a negative pre-charging voltage of the word line.

9. A method for suppressing a current leakage of a memory, the memory comprising at least a memory cell, an equalizing circuit, a current limiter, a word line and a pair of complementary bit lines, the method comprising:
having the memory cell entering a pre-charging mode;
having the equalizing circuit and the current limiter being normally operated, so as for pre-charging the pair of complementary bit lines to a reference voltage; and
applying a periodic control signal to the current limiter for shortening a conducting time of the current limiter, and suppressing a standby current leakage of the memory,
wherein the standby current leakage is generated by the reference voltage over a short circuit between the word line and the pair of complementary bit lines, wherein the logic low level of the periodic control signal is related to a negative pre-charging voltage of the word line.

10. The method according to claim 9, further comprising:
providing an equalization signal for controlling an operation of the equalizing circuit.

11. The method according to claim 9, wherein when the equalizing circuit is normally operated, the bit line and the complementary bit line share charges.

12. The method according to claim 9, wherein the reference voltage is a half of logic high level of the pair of complementary bit lines.

13. The method according to claim 9, wherein the periodic control signal is a square wave or a synthesis sinusoidal wave.
